(19) United States
(12) Patent Application Publication
(10) Pub. No.: US 2006/0268297 A1
(43) Pub. Date: Nov. 30, 2006

(54) Method for constructing a lookup table for converting data from a first color space to a second color space

(75) Inventor: Yao Han, Lexington, KY (US)

Correspondence Address: LEXMARK INTERNATIONAL, INC.;INTELLECTUAL PROPERTY LAW DEPARTMENT, 740 WEST NEW CIRCLE ROAD, BLDG. 082-1, LEXINGTON, KY, 40550-0999, US

(73) Assignee: Lexmark International, Inc.

(21) Appl. No.: 11/136,833

(22) Filed: May 25, 2005

(51) Int. Cl. G03F 3/08

(52) U.S. Cl. 358/1.9; 358/3.23; 358/518

(57) ABSTRACT

A method for constructing a lookup table for converting data from a first color space to a second color space includes generating first data in the first color space corresponding to an input color gamut; representing the first data in a first non-uniform three-dimensional octree structure, wherein an amount of data at any leaf node does not exceed a predetermined threshold; converting the first data to second data in the second color space; and generating a non-uniform three-dimensional octree lookup table relating the first data represented by the first non-uniform three-dimensional octree structure to the second data.

### BACKGROUND OF THE INVENTION

1. Field of the Invention

The present invention relates to imaging apparatus, and, more particularly, to a method for constructing a lookup table for converting data from a first color space to a second color space.

2. Description of the Related Art

An imaging apparatus may be in the form of a multifunction machine, also known as an all-in-one (AIO) machine, which includes scanning and copying capabilities in addition to printing.

The print engine of the AIO may include an ink jet print engine that typically forms an image on a sheet of print media by ejecting ink from at least one ink jet printhead to place ink dots on the sheet of print media. Such an ink jet print engine typically includes a reciprocating printhead carrier that transports one or more ink jet printheads across the sheet of print media along a bi-directional scanning path defining a print zone of the print engine. The bi-directional scanning path is oriented parallel to a main scan direction, also commonly referred to as the horizontal direction. During printing on each scan of the printhead carrier, the sheet of print media is held stationary. An indexing mechanism is used to incrementally advance the sheet of print media in a sheet feed direction, also commonly referred to as a sub-scan direction, through the print zone between scans in the main scan direction, or after all data intended to be printed on the sheet of print media at a particular stationary position has been completed.

Typically, a cartridge, such as a printhead cartridge, is provided that includes a local supply of ink. Such a printhead cartridge may include a multi-chambered ink reservoir for carrying multiple colors of ink, each chamber including a separate supply of ink of a particular color. In one printing system, for example, it is known to include cyan (C), magenta (M) and yellow (Y) inks in one such printhead cartridge, and to provide black (K) ink in another printhead cartridge.

In order to print using CMY or CMYK inks, which may also include dilute as well as full strength inks, it is necessary to convert from monitor red, green and blue (RGB) color values to CMY or CMYK color values. The current application for processing monitor RGB color values is to use a uniform three-dimensional (3D) lookup table (LUT) to reproduce colors in CMY or CMYK color space. This is good for a printer color table process, because the source color gamut, i.e., the monitor RGB, is equally distributed through the color space. However, for color copy and color scan data, the result is less than ideal, since all the input data comes from the scanner.

One reason is that the color gamut after scanning (hereinafter the scanner gamut) is very different from scanner to scanner. For example, a charge coupled display (CCD) scanner typically has a better color distribution and a bigger color gamut than a contact image sensor (CIS) scanner. In addition, in most cases, the scanner gamut is much smaller than the monitor color gamut. Also, the scanner gamut has color data distributions that are nonlinear, especially in dark color areas. Thus, using a standard LUT to process color copy and color scan data has two major drawbacks: first, a large portion of the uniformly distributed color space is wasted for most of the input color gamut; and second, the standard LUT cannot reproduce accurate color in the area in which the scanner data are concentrated and nonlinear.

### SUMMARY OF THE INVENTION

The present invention provides a method for constructing a lookup table for converting data from a first color space to a second color space using a non-uniform three-dimensional octree structure. Accordingly, a non-uniform three-dimensional octree lookup table may be generated to support color copy and color scan modes in a multifunction machine.

The invention, in one form thereof, is directed to a method for constructing a lookup table for converting data from a first color space to a second color space. The method includes generating first data in the first color space corresponding to an input color gamut; representing the first data in a first non-uniform three-dimensional octree structure, wherein an amount of data at any leaf node does not exceed a predetermined threshold; converting the first data to second data in the second color space; and generating a non-uniform three-dimensional octree lookup table relating the first data represented by the first non-uniform three-dimensional octree structure to the second data.

The invention, in another form thereof, is directed to a method for constructing a lookup table for converting data from a first color space to a second color space. The method includes generating first data in the first color space corresponding to an input color gamut; representing the first data in a first non-uniform three-dimensional octree structure, wherein an amount of data at any leaf node does not exceed a predetermined threshold; converting the first data to second data in the second color space, the second data being represented in a second non-uniform three-dimensional octree structure, the first non-uniform three-dimensional octree structure and the second non-uniform three-dimensional octree structure having a corresponding number of data entries; and generating a non-uniform three-dimensional octree lookup table relating the first data represented by the first non-uniform three-dimensional octree structure to the second data represented by the second non-uniform three-dimensional octree structure.

The invention, in one exemplary embodiment, is directed to an imaging apparatus. The imaging apparatus includes a print engine, a scanner and a controller. The controller is communicatively coupled to the print engine and the scanner. A non-uniform three-dimensional octree lookup table is accessed by the controller to process the scanner data generated by the scanner.

### BRIEF DESCRIPTION OF THE DRAWINGS

The above-mentioned and other features and advantages of this invention, and the manner of attaining them, will become more apparent and the invention will be better understood by reference to the following description of embodiments of the invention taken in conjunction with the accompanying drawings, wherein:

FIG. 1 is a diagrammatic depiction of a system embodying the present invention.

FIG. 2 is a flowchart of a method for constructing a lookup table for converting data from a first color space to a second color space, in accordance with an embodiment of the present invention.

FIG. 3 is a three-dimensional graphical representation of scanned RGB data points plotted into RGB color space.

FIG. 4 is a three-dimensional graphical representation of the scanner color space divided into eight equal volume sub-cubes.

FIG. 5 is an exemplary two-dimensional graphical control point representation in RGB color space, wherein R=0, of a further subdivision of selected sub-cubes of FIG. 4, and wherein the black dots represent non-uniform three-dimensional octree control points.

Corresponding reference characters indicate corresponding parts throughout the several views. The exemplifications set out herein illustrate embodiments of the invention, and such exemplifications are not to be construed as limiting the scope of the invention in any manner.

### DETAILED DESCRIPTION OF THE INVENTION

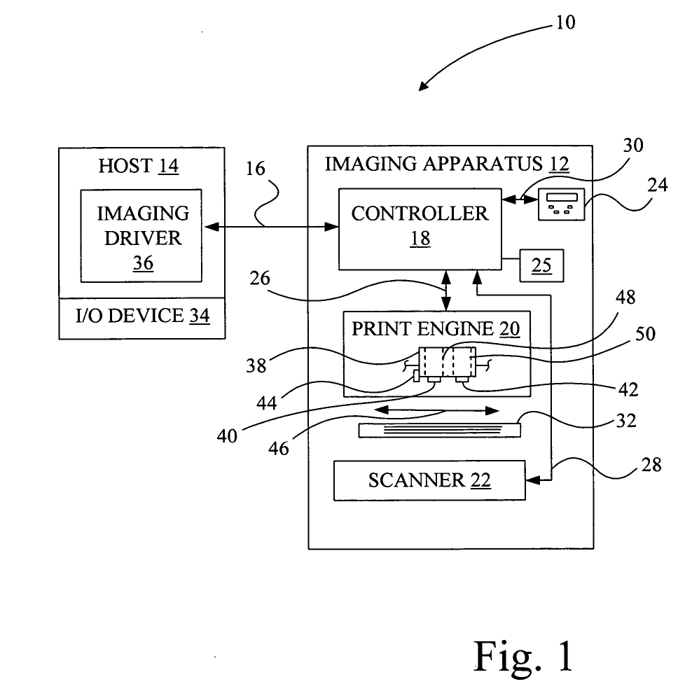

Referring now to the drawings and particularly to FIG. 1, there is shown a diagrammatic depiction of an imaging system 10 embodying the present invention. Imaging system 10 may include an imaging apparatus 12 and a host 14, with imaging apparatus 12 communicating with host 14 via a communications link 16.

Imaging apparatus 12 may communicate with host 14 via a standard communication protocol, such as for example, universal serial bus (USB) or Ethernet. As used herein, the term “communications link” is used to generally refer to structure that facilitates electronic communication between two components, and may operate using wired or wireless technology. Communications link 16 may be established, for example, by a direct cable connection, wireless connection or by a network connection such as for example an Ethernet local area network (LAN).

Alternatively, imaging apparatus 12 may be a standalone unit that is not communicatively linked to a host, such as host 14. For example, imaging apparatus 12 may take the form of a multifunction machine, e.g., an all-in-one (AIO) device, which includes standalone copying and facsimile capabilities, in addition to optionally serving as a printer when attached to a host, such as host 14. Imaging apparatus 12 includes, for example, a controller 18, a print engine 20, a scanner 22 and a user interface 24.

Controller 18 includes a processor unit and associated memory, such as memory 25, and may be formed as an Application Specific Integrated Circuit (ASIC). Controller 18 communicates with print engine 20 via a communications link 26. Controller 18 communicates with scanner 22 via a communications link 28. Controller 18 communicates with user interface 24 via a communications link 30. Communications links 26, 28 and 30 may be established, for example, by using standard electrical cabling or bus structures, or by wireless connection.

In the context of the examples for imaging apparatus 12 given above, print engine 20 may be, for example, an ink jet print engine configured for forming an image on a sheet of print media 32, such as a sheet of paper, transparency or fabric. As an ink jet print engine, for example, print engine 20 operates one or more printing cartridges and/or printheads to eject ink droplets onto the sheet of print media 32 in order to reproduce text and/or images.

Host 14 may be, for example, a personal computer including an input/output (I/O) device 34, such as a keyboard and display monitor. Host 14 further includes a processor, input/output (I/O) interfaces, memory, such as RAM, ROM, NVRAM, and a mass data storage device, such as a hard drive, CD-ROM and/or DVD units. During operation, host 14 includes in its memory a software program including program instructions that function as an imaging driver 36, e.g., printer driver software for imaging apparatus 12. Imaging driver 36 is in communication with controller 18 of imaging apparatus 12 via communications link 16. Imaging driver 36 facilitates communication between imaging apparatus 12 and host 14, and may provide formatted print data to imaging apparatus 12, and more particularly, to print engine 20.

Alternatively, however, all or a portion of imaging driver 36 may be located in controller 18 of imaging apparatus 12. For example, where imaging apparatus 12 is a multifunction machine having standalone capabilities, controller 18 of imaging apparatus 12 may include an imaging driver configured to support a scanning and/or copying function using scanner 22, and/or a fax-print function, and may be further configured to support a printer function. Scanner 22 may be, for example, a bed type scanner with a movable scan bar, or a scanner that transports paper under a stationary scan bar. In the present embodiment, the imaging driver facilitates communication of formatted print data, as determined by a selected print mode, to print engine 20, and facilitates communication of scanned image data to controller 18.

Print engine 20 may include, for example, a reciprocating printhead carrier 38, a color ink jet printhead 40, a monochrome ink jet printhead 42 and (optionally) a reflectance sensor 44. Controller 18 serves to process print data and to operate print engine 20 during printing, as well as to operate scanner 22, process image data obtained via scanner 22, and process printhead alignment data obtained by scanner 22 or reflectance sensor 44. In order for print data from host 14 to be properly printed by print engine 20, the RGB data generated by host 14 is converted into data compatible with print engine 20 and ink jet printheads 40, 42. Likewise, in order for scanner data from scanner 22 to be properly printed by print engine 20, the RGB data generated by scanner 22 is converted into data compatible with print engine 20 and ink jet printheads 40, 42.

Printhead carrier 38 transports ink jet printheads 40, 42 and reflectance sensor 44 in a reciprocation manner along a bi-directional main scan axis 46 over an image surface of the sheet of print media 32 during printing and/or sensing operations. Printhead carrier 38 may be mechanically and electrically configured to mount, carry and facilitate one or more of each of a color printhead cartridge 48 and a monochrome printhead cartridge 50. Each color printhead cartridge 48 may include, for example, an ink reservoir containing a supply of ink, to which at least one respective color ink jet printhead 40 is attached. Each monochrome printhead cartridge 50 may include, for example, an ink reservoir containing a supply of ink, to which at least one respective monochrome ink jet printhead 42 is attached. Alternatively, monochrome ink jet printhead 42 may be replaced by another color printhead, such as a photo printhead for jetting diluted color and mono inks.

In one system using cyan, magenta, yellow and black (CMYK) inks, printhead carrier 38 may carry four printheads, such as printhead 40, with each printhead carrying a nozzle array dedicated to a specific color of ink, e.g., cyan, magenta, yellow and black. As a further example, a single printhead, such as printhead 40, may include multiple ink jetting arrays, with each array associated with one color of a plurality of colors of ink, and printhead carrier 38 may be configured to carry two or more printheads, such as printheads 40, 42. As used herein, the terms CMY and CMYK are intended to include full strength and/or diluted inks of the respective color.

The present invention provides a method for constructing a lookup table for converting data from a first color space, such as a scanner color space of scanner 22, to a second color space, such as a printer color space of print engine 20, using a non-uniform three-dimensional octree structure. Accordingly, a dynamic non-uniform three-dimensional octree lookup table may be generated to support color copy and color scan modes in imaging apparatus 12. The present invention optimally allocates grid points in the non-uniform three-dimensional octree structure according to the scanner characteristics and the input color gamut information. Since the scanner characteristics are known, the input color gamut can be classified (for example, plain paper has smaller color gamut and glossy paper has larger color gamut) in advance at the development stage. In this way, the print engine 20 can produce more accurate colors for color copy and color scan operations performed by scanner 22.

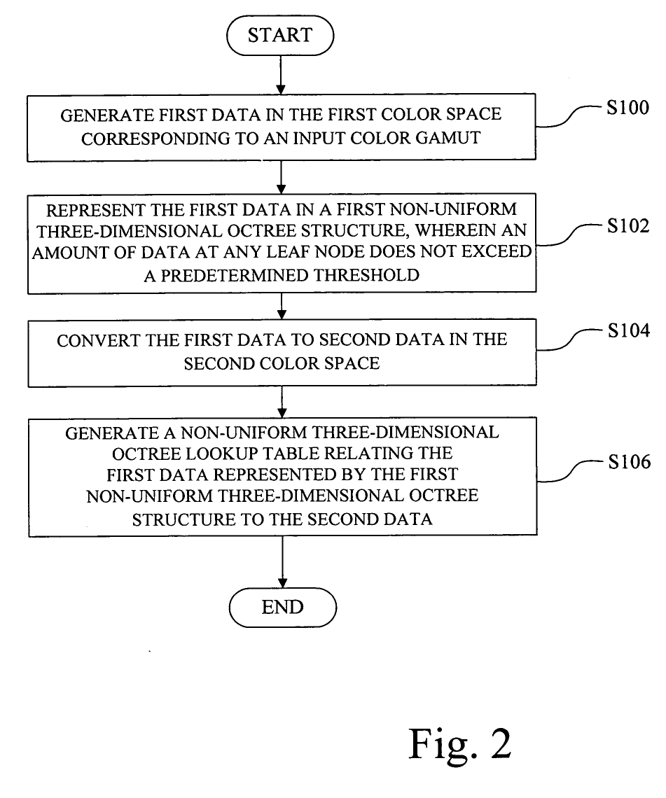

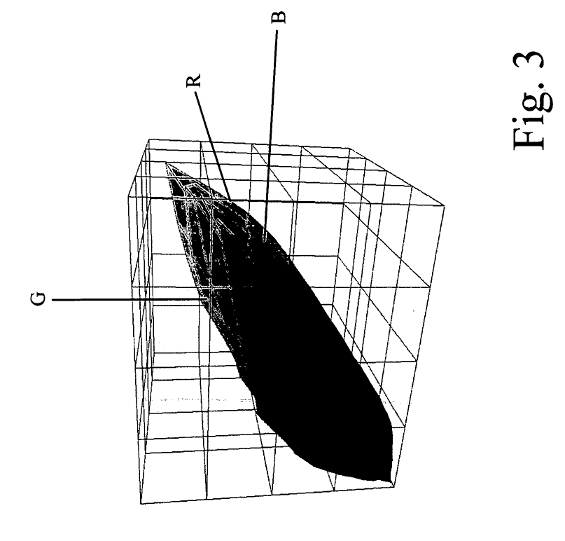

The method now will be described with respect to the flowchart of FIG. 2, with further reference to FIGS. 3-5.

At step S100, input data is generated in the scanner color space of scanner 22 corresponding to an input color gamut of scanner 22. First, for example, n×n×n color patches are printed, such as by using print engine 20. The n×n×n color patches are uniformly distributed in RGB color space representing the monitor color gamut. Uniformly spaced R, G and B values are allocated into n points from 0 to 255. Thus, in a three dimensional monitor RGB color space, for example, the total RGB grid points will be n×n×n. The n value may be, for example, 9, and thus in this example yields 9×9×9=729 grid points. The printed color patches are scanned and saved in an RGB format. RGB values are determined for each pixel, and the average RGB value for each color patch is computed. This provides a preliminary relationship table relating the monitor RGB values and the corresponding scanned RGB values. All scanned RGB data points are plotted into a regular RGB color space, which is illustrated graphically in FIG. 3.

At step S102, the input data is represented in a first non-uniform three-dimensional octree structure, wherein an amount of data at any leaf node does not exceed a predetermined threshold.

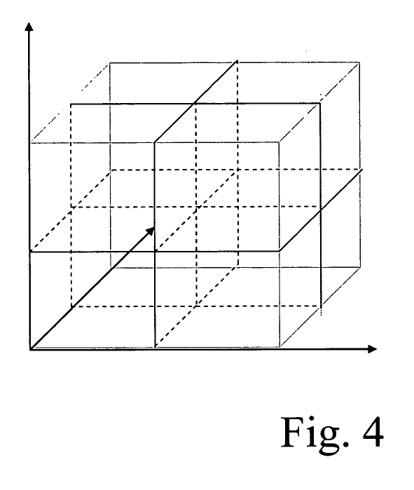

Referring to FIG. 4, the scanner color space is divided into eight equal volume sub-cubes. Each sub-cube has eight corners, and thus, each of the eight sub-cubes may be represented by eight uniformly distributed grid control points. Based on the distribution of the scanner input data, however, some of these sub-cubes with dense data points that exceed a preset threshold are selected for further division. Each of the selected sub-cubes for which the number of associated data points exceeded the preset threshold is then divided into 8 smaller sub-cubes. This process can be repeated as necessary to form leaf nodes, i.e., until each sub-cube contains approximately the same number of data points, or until a preset maximum number of iterations (subdivisions) is reached.

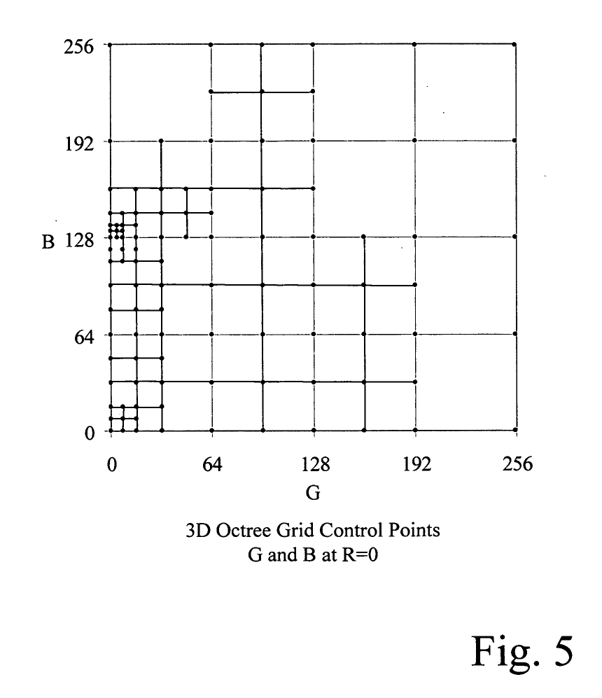

FIG. 5 is an exemplary two-dimensional graphical control point representation in RGB color space, wherein R=0, of a further subdivision of selected sub-cubes of FIG. 4, and wherein the black dots represent non-uniform three-dimensional octree control points. With respect to the octree structure, all leaf nodes are represented as grid control points.

Due to the characteristics of the RGB scanner color space (RGB values are from 0 to 255), the maximum number of subdivisions is selected to be eight. In this way, each of the sub-cubes, although they may have different volumes, and thus the octree structure is non-uniform in volume, the octree structure contains no more than a predetermined number of data points and can be represented by a tri-linear or tetrahedral interpolation algorithm uniformly. Nonetheless, in the whole color space, each sub-cube of the octree structure will have eight control points, regardless of the size of the sub-cube.

More particularly, the data points from the 729 averaged RGB color patch scanned data are computed for each sub-cube. For example, the number of data points in each sub-cube may be denoted to be: n[0], n[1], . . . , n[7].

```
For (i=0; i<8; i ++)
      If (n[i]>K)
        perform sub-cube division to divide this cube into 8 sub-cubes
      Else
        Stop
```

K is a threshold, and is selected based on, for example, the total number of input color patches and the desired size of the leaf node. In this example, K=4 and defines the minimal size of the leaf node to be 4 and the maximum size of the leaf node to be 64. This definition constrains the depth of the Octree structure within the range from level 2 to level 6. For example, consider level 0=256; level 1=128; level 2=64; level 3=32; level 4=16; level 5=8 and level 6=4.

Thus, the present invention dynamically arranges the control points over the scanner color space based on the distribution of the scanner data derived from the color patches. The more concentrated, i.e., dense, the data is in a particular region, the more control points are assigned to that particular region. However, since the size of the sub-cube is larger for regions that are less dense, the number of control points needed to define the region is smaller than in the dense region of similar volume. In this example, the non-uniform three-dimensional octree structure may have only 1312 control points, and the smallest size of the cube is 4. In contrast, the number of control points needed in a uniform LUT structure is 65×65×65=274625 control points in order to get the same level of color reproduction accuracy. Thus, a considerably lesser number of control points is needed by the present invention to accurately represent the input data.

At step S104, the input data is converted to second data in the printer color space of print engine 20. In other words, for example, the RGB non-uniform three-dimensional octree control points determined in step S102 are converted to CMY, or CMYK, non-uniform three-dimensional octree control points. Thus, in effect, the second data (e.g., CMY or CMYK data) is represented in a second non-uniform three-dimensional octree structure. Accordingly, the first non-uniform three-dimensional octree structure and the second non-uniform three-dimensional octree structure have a corresponding number of data entries. For example, once the non-uniform three-dimensional octree structure is obtained in the source color space (scanner RGB color space), then the data is converted to a non-uniform three-dimensional octree structure in the destination color space, e.g., CMY or CMYK color space.

At step S106, a non-uniform three-dimensional octree lookup table is generated relating the input data represented by the first non-uniform three-dimensional octree structure to the second data, represented by the second non-uniform three-dimensional octree structure. In particular, the values from the destination color space corresponding to all leaf nodes in the source color space are tabulated into the first non-uniform three-dimensional octree structure of the source color space.

The non-uniform three-dimensional octree lookup table is stored in a memory associated with imaging apparatus 12. For example, the non-uniform three-dimensional octree lookup table may be stored in memory 25 that is accessible by controller 18 for use in performing color copy and color scan operations using imaging apparatus 12 operating in a standalone copy or scan mode. The non-uniform three-dimensional octree lookup table is then accessed by controller 18 to process scanner data generated by scanner 22. The processed scanner data may then be printed by print engine 20.

Alternatively, however, the non-uniform three-dimensional octree lookup table may be stored at other locations accessible for use with imaging apparatus 12, such as for example, in host 14.

The generated non-uniform three-dimensional octree lookup table is spatially presorted. Accordingly, when the non-uniform three-dimensional octree lookup table is used to process scanner data, non-lattice points are interpolated by using the nearest lattice points. All points of the RGB data from scanner 22 are examined. A series of comparisons are used to locate the nearest lattice points. The decision logic is applied recursively until the lattice points are leaf nodes in the non-uniform three-dimensional octree lookup table, thereby indicating that the nearest lattice points have been determined.

While this invention has been described with respect to embodiments of the invention, the present invention may be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains and which fall within the limits of the appended claims.

What is claimed is:

1. A method for constructing a lookup table for converting data from a first color space to a second color space, comprising:
generating first data in said first color space corresponding to an input color gamut;
representing said first data in a first non-uniform three-dimensional octree structure, wherein an amount of data at any leaf node does not exceed a predetermined threshold;
converting said first data to second data in said second color space; and
generating a non-uniform three-dimensional octree lookup table relating said first data represented by said first non-uniform three-dimensional octree structure to said second data.

2. The method of claim 1, wherein said second data is represented in a second non-uniform three-dimensional octree structure.

3. The method of claim 2, wherein said first non-uniform three-dimensional octree structure and said second non-uniform three-dimensional octree structure have a corresponding number of data entries.

4. The method of claim 1, wherein said first color space is RGB color space and said second color space is one of CMY color space and CMYK color space.

5. The method of claim 1, wherein said non-uniform three-dimensional octree lookup table is stored in a memory associated with an imaging apparatus.

6. The method of claim 1, wherein said first non-uniform three-dimensional octree structure includes a plurality of sub-cubes, some of said plurality of sub-cubes being non-uniform in volume with respect to other of said plurality of sub-cubes.

7. The method of claim 6, wherein no sub-cube in said first non-uniform three-dimensional octree structure contains more than a predetermined number of data points of said first data, said predetermined number corresponding to said predetermined threshold.

8. A method for constructing a lookup table for converting data from a first color space to a second color space, comprising:
generating first data in said first color space corresponding to an input color gamut;
representing said first data in a first non-uniform three-dimensional octree structure, wherein an amount of data at any leaf node does not exceed a predetermined threshold;
converting said first data to second data in said second color space, said second data being represented in a second non-uniform three-dimensional octree structure, said first non-uniform three-dimensional octree structure and said second non-uniform three-dimensional octree structure having a corresponding number of data entries; and
generating a non-uniform three-dimensional octree lookup table relating said first data represented by said first non-uniform three-dimensional octree structure to said second data represented by said second non-uniform three-dimensional octree structure.

9. The method of claim 8, wherein each of said first non-uniform three-dimensional octree structure and said second non-uniform three-dimensional octree structure includes a plurality of sub-cubes, some of said plurality of sub-cubes being non-uniform in volume with respect to other of said plurality of sub-cubes.

10. The method of claim 9, wherein no sub-cube in said plurality of sub-cubes of said first non-uniform three-dimensional octree structure contains more than a predetermined number of data points of said first data, said predetermined number corresponding to said predetermined threshold.

11. The method of claim 9, wherein no sub-cube in said plurality of sub-cubes of said second non-uniform three-dimensional octree structure contains more than a predetermined number of data points of said second data, said predetermined number corresponding to said predetermined threshold.

12. An imaging apparatus, comprising:
a print engine;
a scanner;
a controller communicatively coupled to said print engine and said scanner; and
a non-uniform three-dimensional octree lookup table accessed by said controller to process scanner data generated by said scanner.

13. The imaging apparatus of claim 12, wherein said processed scanner data is printed by said print engine.
